(19) United States
(12) Patent Application Publication
(10) Pub. No.: US 2011/0217505 A1
(43) Pub. Date: Sep. 8, 2011

(54) Low-Defect nitride boules and associated methods

(75) Inventor: Michael Joseph Callahan, Hanson, MA (US)

(73) Assignee: TELEOLUX INC., Hanson, MA (US)

(21) Appl. No.: 13/021,712

(22) Filed: Feb. 5, 2011

Related U.S. Application Data
(60) Provisional application No. 61/301,638, filed on Feb. 5, 2010.

(51) Int. Cl. B32B 3/02; C30B 23/00; C30B 25/00; C30B 7/00; B32B 43/00

(52) U.S. Cl. 428/80; 117/84; 117/68; 156/712

(57) ABSTRACT

This invention describes Extreme low-defect Nitride Boules and associated methods of manufacture using low-defect seed templates or composite templates arranged in precise hexagonal or partial hexagonal crystal facets, and nearly exact lattice and thermal expansion coefficient matching of a low-defect nitride template or composite template with a thick nitride boule grown upon said template or composite template through alloying and doping. Reduction of the critical thickness of said template or composite template and said boule by thinning of template or composite template is also described.

### CROSS REFERENCE TO RELATED APPLICATIONS

This application claims the benefit of provisional application Ser. No. 61/301,638 filed Feb. 5, 2010 by present inventor

### FEDERALLY SPONSORED RESEARCH

Not applicable

### SEQUENCE LISTING OR PROGRAM

Not applicable

### TECHNICAL FIELD OF INVENTION

The present invention relates to semiconductor materials, in particular, relates to gallium nitride and other nitride materials, and more particularly relates to methods in manufacture of very low defect single crystalline gallium nitride boules and other III-N boules and processing of said boules into low-defect GaN and III-N wafers.

### BACKGROUND OF THE INVENTION AND RELATED ART

The success of the semiconductor industry is in a large part due to the availability of large diameter single crystal wafers processed from low-defect large-diameter boules grown by molten techniques. Dislocations form during solidification of single crystals boules when the strain (deformation) in the crystal exceeds a given limit. This is know in the art as the Critical Resolved Shear Stress (CRSS) in bulk single crystals and is caused by slight variations in the temperature, crystal structure, and external stresses during the growth process. Current state of the art processing conditions allow for extremely uniform temperature gradients and mitigation of impurities to very low levels in the industrial growth of large-diameter silicon boules. The Si boules, which are free of dislocations—the defect most responsible low yields in Si CMOS devices, are then processed into large-diameter silicon wafers for the semiconductor industry.

GaN (gallium nitride) and its corresponding alloys AlN (aluminum nitride) and InN (indium nitride) are emerging semiconductors materials that are the basis for green-ultraviolet laser diodes and LEDs, High-power high-frequency RF and MM wave devices, and a variety of other novel devices. The market for GaN-based devices reached $4.6B in 2008. Currently the majority of all devices are grown from non-nitride substrates. This is due because GaN, InN, and AlN cannot be grown by molten techniques mentioned above on an industrial scale due to the high temperatures and extreme pressures required to melt these materials. Because of this the majority of gallium nitride and other nitride thin films are grown on currently available commercially substrates such as Si, SiC, and Sapphire.

Semiconductor thin films grown on substrates or templates of a different lattice structure or with a different lattice constant than that of the film, such as GaN grown on sapphire, generates biaxial strain in both the film and the template (substrate) the film is grown upon. Biaxial strain at the interface of the template (substrate) and film (epilayer) is due to thermal and lattice mismatch of the substrate and epilayer, the thickness of both the substrate and epilayer, and the intrinsic mechanical properties of the substrate and epilayer. The thickness where the biaxial strain causes plastic stress to occur, through the formation of misfit dislocations or line defects, and to a lesser degree formation of point, planar, and volume defects, is called the critical thickness (CT). Biaxial strain and thus CT is temperature dependent. Current commercial nitride-based devices manufactured on heterogeneous substrates such as sapphire have large numbers of defects due to the critical thickness of nitride films being exceeded. These defects in nitride thin films on heterogeneous substrates causes reduced yield, low performance, and reduce lifetimes.

Thus large-diameter, low-cost, low-defect GaN and other group III-nitride wafers from thick nitride boules are desired for improved electronic devices and optoelectronic nitride-based devices. The market for nitride substrates is projected to be several billion dollars per year if low-cost large-area lower-defect nitride substrates become available.

Since the group III-nitrides cannot be economically grown by molten techniques, vapor and solution growth techniques are employed. Vapor growth technology for GaN boules is more mature and currently dominates the commercial marketplace.

Current state of the art commercial GaN wafers grown by hydride vapor phase epitaxy (HVPE) have high numbers of various defects which limit nitride device performance and reduce yields. This is due to the fact that these wafers where originally grown on heterogeneous substrates. These high-defect wafers, which are also used as templates for thick GaN boule growth, significantly retard the ability to grow GaN boules of large vertical scale (thickness) due to the large number of defect in the templates which propagate into the GaN boule.

There are very limited quantities of very low-defect GaN grown by solution growth techniques such as flux growth and the ammonothermal technique which could be used for low-defect templates for HVPE growth, but GaN grown from the ammonothermal and flux techniques have slight variations in lattice constants from HVPE grown GaN. The lattice mismatch of these seeds to the HVPE GaN grown upon them limits the thickness that can be grown before a large number of defects are generated when the critical thickness (CT) is reach between the seed template and growing HVPE GaN boule. Furthermore, the limited quantity of these templates, small surface area, and slow growth rates of both the ammonothermal and flux processes severely constrains the ability to use large numbers of templates grown by solution techniques to rapidly scale the HVPE manufacturing process to fulfill the high demand for low-defect, large-area, low-cost GaN wafers. The following references further delineate the problems that arise when using low-defect GaN substrates from flux growth as seeds or templates for HVPE boule growth.

V. Darakchieva, B. Monemar, A. Usui, M. Saenger and M. Schubert, Lattice parameters of bulk GaN fabricated by halide vapor phase epitaxy, Journal of Crystal Growth 310, (2008), 959-965 analyzes differences in lattice parameters for GaN fabricated by HVPE, high pressure Ga flux growth (HP GaN), and homo-epitaxial GaN layers grown upon HP GAN. Darakchieva et. al go on to say that changes in lattice parameters can be caused by i) Incorporation of Impurities ii) presence of native point defects iii) presence of extended and 3D defects iv) growth induced and thermally induced strain for hetero-epitaxial layers. The authors also state that Si and Be impurities are know in the literature to contract the lattice; and O and Mg impurities are know to expand the lattice, but go on to state that it is unknown how native defects (deficient or additional Ga and N atoms in the GaN crystal lattice) and their complexes effect strain, i.e. they could either expand or contract the crystalline lattice. They also state that complex defects, precipitates and complex pyramidal defects can affect the crystalline lattice by size effects and thermal expansion coefficient differences with the matrix. The authors state the specific case where the smaller lattice constants of High Pressure Ga flux grown GaN doped with Mg may be due to pyramidal defects from Mg clusters. The authors speculate the pyramidal defects are empty and expected to contract the lattice, thereby compensating the expansion due to the expansion from the Mg and Oxygen which are at ˜10²⁰ cm⁻³. They go on to state that the evaluation of the size effect for the HP GaN: Mg may be further complicated by a possible presence of N vacancies and complexes, MgO, Mg-O-N clusters with unknown effect on the lattice parameters. The authors state that HVPE GaN may have residual strain which is present as bowing, which varies with thickness and nucleation schemes, and suggest that this could expand lattice constants.

I. Grzegory, B. Lucznik, M. Boc'lowski, S. Porowski, Crystallization of low dislocation density GaN by high-pressure solution and HVPE techniques, Journal of Crystal Growth 300 (2007) 17-25 claimed that a lattice mismatch ˜1.6×10⁻⁴ of their HP GaN to HVPE material (see FIG. 1 in this application) which was experimentally determined to correspond to a critical thickness of 30-50 μm when the authors used the HVPE technique to grow HVPE GaN on HP GaN templates. Growth above this critical thickness resulted in substantial generation of defects. The authors reduced the number of defects by growing with the HVPE technique less than the critical thickness, removing the HP GaN template by mechanical polishing which relieved the elastic stress of the HVPE growth, and re-growing HVPE GaN. This method was somewhat successful in generation of lower defect GaN but there was substantial amount of defects generated upon re-growth. However, these GaN crystals could not be used as templates for HVPE growth to rapidly scale industrial HVPE production because HP GaN substrates are extremely expensive to produce, and are not available in the large surface areas and large diameters needed in order to produce large diameter GaN boules. Furthermore the technique Grzegory et. al used above is not proven to work for producing low defect boules that are many millimeters thick.

The references discuss above clearly show the variation of the lattice constants and defect composition of thick HVPE GaN boules depends on the growth conditions and techniques used and the impurities, structure, and atomic spacing (lattice constants) of the template that the GaN is grown on. The state of the art of HVPE GaN boule growth is clearly lacking in providing suitable templates and/or growth conditions in order to provide thick low-defect GaN boules.

Therefore there is a need for a method which can produce large quantities of low-defect, large-surface-area GaN templates and use these same templates to produce thick large-surface-area HVPE GaN boules on the industrial scale necessary to fulfill the demand for large numbers of low-cost, low-defect, large-diameter GaN and other group III-N wafers.

### SUMMARY OF THE INVENTION

This invention provides methods for producing low-defect single crystal M-nitride boules and semiconductor nitride substrates from said M-nitride boules wherein M=the elements of Group III of the periodic table including group IIIA, which include the elements of scandium (Sc) and yttrium (Y), and group IIIB, which include the elements of boron (B) gallium (Ga), aluminum (Al), indium (In), and thallium (Tl), and all corresponding alloys of group III nitrides such as: InGaN, InAlN, AlGaN, AlBN, ScGaN, AlGaInN, etc.

There are five primary sub-methods this invention uses to achieve low-defect IIIN boules:
1. Lateral Overgrowth and Wafer Bonding
   a. Lateral or perpendicular growth on high-defect GaN nitride templates which have at least one long edge and at least one short edge where the long edge is preferably preferentially orientated along one of the major hexagonal facets (planes) or directions i.e. C-plane (100), A-plane (112), M-plane (110), or other planes that are nearly lateral to the majority of misfit dislocations or other defects
   b. Precisely cutting the original high defect seeds out of the newly grown material to leave two or more low-defect strips, polishing and bonding said long edges of multiple strips to form a complete or nearly complete major hexagonal facet (planes) mention in sub-method 1a.
   c. Using said facet in sub-method 1b as low-defect template for the growth of low-defect thick GaN boules.
2. Growth on fully faceted or nearly fully faceted templates: Templates can be obtained from method 1 or by any other method or process. Preferred faceting of templates is one of the major facets or lattice planes of the P6₃/mmc space group such as the (100) C-plane, (111) A-plane, and the (100) M-plane as shown in FIGS. 7A, 7B, and 7C.
3. Exact lattice and thermal expansion matching of fully faceted template of method 1 or 2 to boule (Growth on template) by alloying and doping template or boule or both the template and boule which will allow for extremely thick low-defect III-N boules to be manufactured.
   a. Lattice and/or thermal expansion matching can be accomplish by doping or alloying template to lattice match boule:
   b. Lattice matching and/or thermal expansion can be accomplished by doping or alloying boule to closely match the lattice constants of the template.
   c. Lattice matching and/or thermal expansion can be accomplished by doping or alloying boule and template.
   d. In cases where an exact lattice matching and/or thermal expansion matching is problematic, boule thickness can be below or above critical thickness (CT) to allow for either a strained boule with very low number of defects or a low-strained boule with a slightly higher number of defects
   e. New templates can be cut from the boule and processed (etched, polished, heated, etc.) to remove defects or strain
   f. These new templates can be successively used to grow improved thicker boules with lower defects
4. Near exact lattice matching and template thinning to allow critical thickness(CT) of the template and boule growth to be greater than the actual thickness of the template (Tₜₑₘₚₗₐₜₑ)
   a. Easier to conceptualize if the template is thought as the thin film and the boule growth is thought as the substrate (Turn template and boule upside down)
   b. Thickness of template (Tₜₑₘₚₗₐₜₑ) is less than Thickness of the boule (T_{boule})
   c. Making the CT>Tₜₑₘₚₗₐₜₑ; and T_{boule}>>Tₜₑₘₚₗₐₜₑ will allow for unlimited thickness of boule with no defects generation and nearly all the strain would reside in the template and not in the boule.
   d. Near exact lattice matching may be accomplished by method 3.
5. Laser liftoff of nearly defect-free thick (<100 um) nitride alloy layers from thick nearly defect free nitride substrates by growth below CT and modification lattice parameters and absorption properties of substrate and/or thin film by point defects
   a. Can use substrates or templates multiple times
   b. Can adjust frequency and power profile of laser source for matching of absorption profile of substrate and/or thick film to allow optimization of lift off process.
   c. Can achieve point defects by doping
   d. Point defects can be intrinsic or extrinsic
   e. Can grow thick layer on multiple substrates simultaneously
   f. Can use any growth technique to grow thick layers on substrates i.e. flux, ammonothermal, vapor growth, MBE, MOCVD, and HVPE

The sub-methods above could be successively used multiple times to achieve desired lattice constants, defect levels, conductivity, III-N composition, transparency, and other properties by using different concentrations and combinations of incorporating dopants and alloys in both template and boule during growth and post processing techniques such as annealing at high temperature in a high partial pressure of nitrogen. These methods above can be applied multiple times with slight modifications of one or more aspects of the methods to achieve desirable qualities of said nitride substrates such as low defect levels, large surface areas, thick boule production, high or low conductivity, etc.

The terms used herein should be understood as having the meanings defined below in the present specification:

The term “gallium nitride” or “GaN” is any material substantially composed of the atomic elements gallium and nitrogen.

The term “aluminum nitride” or “AlN” is any material substantially composed of the atomic elements aluminum and nitrogen.

The term “indium nitride” or “InN” is any material substantially composed of the atomic elements indium and nitrogen.

The term “AlGaN alloy” or “AlGaN” is any material substantially composed of the atomic elements aluminum, gallium, and nitrogen

The term “InGaN alloy” or “InGaN” is any material substantially composed of the atomic elements, indium, gallium, and nitrogen

The term “AlnN alloy” or “AlInN” is any material substantially composed of the atomic elements aluminum, indium, and nitrogen

The term “AlGaInN alloy” or “AlGaInN” is any material substantially composed of the atomic elements aluminum, gallium, indium and nitrogen

The term “III-N” or “nitride alloy” or “metal nitride” or “MN” is a material substantially composed of the chemical element nitrogen and any element or elements in Group III of the periodic table using the American CAS numbering system, including group IIIA (equivalent to group 3 in the new IUPAC numbering system) which include the elements of scandium (Sc) and yttrium (Y), and group IIIB (which is equivalent to group 13 in the new numbering IUPAC system) which include the elements of boron (B) gallium (Ga), aluminum (Al), indium (In), and thallium (Tl) and all corresponding alloys of group III nitrides such as: InGaN, InAlN, AlGaN, AlBN, ScGaN, AlGaInN, etc.

The term “single crystal” or “single crystalline material” is any material in which the crystal lattice of the entire sample is substantially continuous and unbroken to the edges of the sample, with substantially no grain boundaries.

The term “polycrystalline” is any material that is composed of many smaller single crystals of varying size and orientation and has many grain boundaries.

The term “grain boundary” is the interface between two single crystals in a polycrystalline material.

The term “template” or “seed” or “seed template” or “matrix” is the initial material or materials used to grow single crystalline layers or boules upon.

The term “thick layer” is defined to be between 5-200 μm of growth on top of a substrate or wafer.

The term “strip” is high defect crystalline material cut or removed from crystalline material that will be used to grow a low defect piece or pieces by lateral growth.

The term “low defect piece” or “piece” is defined as low defect single crystal piece that are cut or removed from a high-defect strip.

The term “composite template” is a template that is formed by a plurality of smaller sub-templates or pieces that are touching or affixed in such as a way as to from a fully contiguous template.

The “sub-template” is a smaller composite template, template, or piece that is connected with other smaller composite templates, sub-templates, or pieces to from a larger composite template.

The term “boule” is the thick single crystalline material that is grown upon a “template”.

The term “substrate” or “wafer” is a thinner single crystalline material that is cut or removed from a thicker single crystalline “boule”. Said substrate can be polished and prepared in such way as to produce optical or electronic semiconductor devices on said substrate or wafer. Said wafer is typically 50-1000 μm thick.

The term “crystal structure” or “crystal lattice” is a precise repeating arrangement of atoms is a single crystal.

The “crystalline material” is a material or chemical compound that is made up of one or more contiguous crystalline sections or grains. It can be polycrystalline, high-defect single crystal, or low defect single crystal and herein is defined as one connected contiguous mass that will not easily crumble or separate.

The term “lateral growth” is growth perpendicular or nearly perpendicular to the direction the majority of threading dislocations or other defects propagates in a crystalline material. It can also be defined as growth perpendicular to the majority of the highest aspect grain boundaries in a crystalline material.

The term “hexagonal prism” is a prism with two hexagonal parallel bases by 6 rectangular sides.

The term “hexagonal facet” is a surface or plane of hexagonal wurtzite (wz) C⁴₆ᵥ crystals in which examples are defined above i.e. “c-plane”, “a-plane”, and “m-plane”.

The term “dopant” is an additional element, compound, or point defect purposely added to the nitride crystal to change its electrical, optical, structural, or any other desired properties of said nitride crystal.

The term “impurity” is an additional element, compound, or point defect unintentionally added to the nitride crystal to change its electrical, optical, structural, or any other desired properties of said nitride crystal.

The term “point defect” or “0D” are intrinsic or extrinsic zero dimensional defects that can be one or more dopants and/or impurities.

The term “line defect” or “1D” is a one dimensional defect or line they are often called misfit dislocations.

The term “surface defect” or “2D” is a defect consisting of a two dimensional surface or plane of defects and are often called stacking faults.

The term “volume defect” or “3D” are complex three dimensional defects such as voids, semi-voids, large cracks or trenches or bubbles or other 3D portions of the crystal filled with impurities and/or volume defects.

The term “low-defect” is defined in this specification as single crystal material with less than 10⁵ misfit dislocations, stacking faults, and non-point 1D, 2D, or 3D defects.

The term “thermal expansion” is an indication of the expansion or contraction of a single crystal due to temperature.

The term “thermal expansion coefficient” is a quantitative measurement of the expansion or contraction of a single crystal due to temperature

The term “thermal mismatch” is a difference of thermal expansion coefficients of two different single crystals or materials.

The term “HYPE” is a form of crystal growth for vapor. It stands for hydride vapor phase epitaxy.

The term “flux growth” is a form of crystal growth where a crystal is grown in a solution or melt that has common elements of the desired crystal grown but is not of the exact composition, chemical makeup, or molar ratios of the crystal that is synthesized from said flux.

The term “ammonothermal growth” is a form of solvothermal growth or growth from high pressure solvents, wherein ammonia is used as a solvent to grow crystals.

The term “DEEP technique” is a HVPE technique used by Mitsubishi Chemical to grow GaN on a GaAs substrate where defects are confined to regions or “stripes” and substantial areas of the HVPE GaN have low defects.

The term “vapor growth” is defined as growing a crystal or chemical compound by chemical reaction in the gaseous or vapor phase.

The term “unit cell” is the simplest form of a precise repeating arrangement of atoms in a single crystal.

The term “lattice constant” or “lattice parameter” is the distance between unit cells in a crystal lattice.

The term “lattice mismatch” is the difference in lattice constants of two single crystalline materials and is defined herein as: [(lattice constant of the template)/(lattice constant of boule)-1]. Lattice mismatch will prevent growth of defect-free epitaxial film unless thickness of the film is below certain critical thickness; in this last case lattice mismatch is compensated by the strain in the film.

The term “pseudomorphic material” is a layer of single-crystal material on a single-crystal template or substrate whose lattice mismatch is accommodated by elastic strain in the layer when the layer is thinner than the critical thickness (h_{c}) of the layer.

The term “strained layer superlattice” or “SLS” is a structure comprising of several epitaxial layers of lattice mismatched materials thin enough to avoid formation of misfit dislocations.

The term “critical thickness” or “hc” or “CT” is the minimum level at which misfit dislocations are introduced in a layer of material grown on a template that has a different crystal lattice or lattice parameter than the material grown. Below critical thickness misfit strain is accommodated elastically (stretching of lattice: strain removed when stress is removed i.e. removal of substrate), above critical thickness misfit strain is accommodated plastically, where misfit dislocations and other defects are generated.

The term “misfit dislocation” is the dominant crystallographic defect, or irregularity, within a crystal structure. Misfit dislocations compensate for differences in the lattice constants by concentrating the misfit in one-dimensional regions—the dislocation lines.

The term “elastic strain” is deformation of a material that is reversible once force is removed from the material is returned to its original shape.

The term “plastic strain” is deformation of a material that is not reversible once the force is removed the material remains deformed.

The term “biaxial strain” is strain in the crystal lattice along two axes typically perpendicular to each other.

The term “Residual stresses” are stresses that remain after the original cause of the stresses has been removed such as removing a template of different lattice constants from a layer or a boule that has been grown on said template.

The term “bowing” is curvature of a template, boule, or substrate due to residual stresses after the growth process or method.

The term “c-axis” is the [0001] direction of hexagonal wurtzite (wz) C⁴₆ᵥ crystals

The term “a-axis” is the [10-12] direction of hexagonal wurtzite (wz) C⁴₆ᵥ crystals

The term “m-axis” is the [10-10] direction of hexagonal wurtzite (wz) C⁴₆ᵥ crystals

The term “c-plane is the {0001} surface of hexagonal wurtzite (wz) C⁴₆ᵥ crystals

The term “a-plane is the {11-20} surface of hexagonal wurtzite (wz) C⁴₆ᵥ crystals

The term “m-plane is the {10-10} surface of hexagonal wurtzite (wz) C⁴₆ᵥ crystals

### BRIEF DESCRIPTION OF THE DRAWINGS

FIG. 1: Duplication of FIG. 5 of Darakchieva et. al incorporated herein as a reference for the background of the invention which shows variations in lattice constants of GaN manufactured by different growth techniques. Lattice parameters a and c for bulk and free-standing (FS) GaN fabricated by HVPE, HP bulk GaN, and homo-epitaxial GaN layer copied from: V. Darakchieva, B. Monemar, A. Usui, M Saenger and M. Schubert, Lattice parameters of bulk GaN fabricated by halide vapor phase epitaxy, Journal of Crystal Growth 310, (2008), 959-965

FIG. 2 shows low defect a-plane {11-20} lateral growth of single crystalline nitride material on high defect seed

FIG. 3 shows low defect a-plane {11-20} lateral growth areas cut out from high defect seed

FIG. 4 shows low defect a-plane {11-20} lateral growth areas from FIG. 2 arranged in such a way as to form fully faceted wurtzite hexagonal C⁴₆ᵥ crystallographic structure in which the top large area surface is the c⁺-plane (0001)

FIG. 5A shows the use of a holder around subsections in FIG. 3 to aid in containment of subsections in the wurtzite hexagonal C⁴₆ᵥ crystallographic structure

FIG. 5B shows low defect m-plane {10-10} lateral growth subsections forming the wurtzite hexagonal C⁴₆ᵥ crystallographic structure in which the top large area surface is the c⁺-plane (0001) along with optional holder

FIG. 6 shows the fully faceted wurtzite hexagonal C⁴₆ᵥ crystallographic structure in FIG. 5A or FIG. 5B without optional holder as a composite template to growth a thick faceted hexagonal prism

FIG. 7 shows the use of a low-defect c-plane template (FIG. 7A), a low-defect a-plane template (FIG. 7B), and a low-defect m-plane template (FIG. 7C) to grow thick 3D faceted group III nitride boules in the geometrical form of hexagonal prism or half prisms

### DETAIL SPECIFICATION AND PREFERRED EMBODIMENTS OF THE INVENTION

This invention can be applied to form low-defect single crystal metal nitride boules and wafers from such boules and could also be used to obtain low defect single crystalline material that can not be grown by molten techniques.

GaN and other III-Nitrides will be used in the following discussions as a representative example. The methods herein could be applied to any nitride crystalline materials and even any crystalline material. One could reasonably use many of the currently know growth techniques in the art and by applying the methods discussed herein free-standing, high-defect, large-surface area GaN crystalline or III-N templates with 10 μm or greater thickness can be manufactured. These templates then can be used in many of the currently known growth techniques in the art, including HVPE, MOCVD, Flux growth, and Ammonothermal growth to grow low-defect, large surface area, large volume GaN or other III-N boules using the methods shown herein and discussed in detail below.

As just stated, the first requirement to grow low-defect boules that cannot be grown by molten techniques is to provide a large-area low-defect template in which the boule will be grown. The template needs to be of a large surface area on the face or plane in which growth is to occur and have high crystalline perfection with a low number of line, planar, and volume defects. The template must also have a close lattice match of less than around 10⁻⁴, a close thermal expansion match of less than around 10%, and also be chemically compatible to the material being grown upon the template.

Since the III-nitrides are difficult to grow by molten techniques, large single crystals of the III-nitrides are not produced in nature, and there is no commercially available substrate or template that meets the requirements in the preceding paragraph, current methods grow III-N boules on templates that have lattice and thermal expansion mismatches of much greater than 1%.

The most common practice is to grow HVPE GaN on a sapphire wafer in the c-axis direction to a thickness of several millimeters in the c-axis direction and remove the sapphire wafer from said HVPE GaN crystal. This state of the art HVPE GaN is highly defective with low angle grain boundaries, threading dislocations, and regions of polycrystalline material and grain boundaries.

Other ways to obtain a high-defect crystalline layer of GaN could be by MBE, MOCVD, PLD, low temperature solution growth, flux growth, ammonothermal growth, or any technique that produces GaN or Group III Nitrides or for that matter any crystalline material or compound that is free standing and greater than 10 μm in thickness.

It is know in the art that lateral growth from a high-defect layer produces material that has a substantially lower number of dislocations. It has been shown that large-area low-defect GaN single crystals can be produce by merging laterally grown material from HVPE GaN templates using the ammonothermal technique, Dwilnski et al., international patent application PCT/JP2005/02239 included herein as a reference.

The ammonothermal technique has low growth rates and the techniques Dwilinski et. al used for scaling to large wafer sizes and growth of low-defect boules required many iterations and many years of development. Current know state of the art HVPE growth has high growth rates of greater than 50 times ammonothermal growth but cannot produce low-defect templates that are required for low-defect boules.

The first method discussed herein method 1 produces low-defect III-nitride templates preferable for use in high growth rates boules manufacturing processes such in HVPE.

First a current technique such as HVPE know in the art would be used to grow free standing GaN or group III-N material. Preferably the crystalline material is single crystal or nearly single crystal, albeit with a large number of defects such as material seen by current state of the art free standing GaN material grown by MOCVD or HVPE on sapphire. The grain, sections, or sub-grains of this material would preferably be generally aligned in one crystallographic orientation to substantially reduce the number of defects when new single crystal material is grown on the surface of a crystallographic orientation that is generally perpendicular or lateral, i.e. “lateral growth”, to crystallographic material just discussed.

The high-defect crystalline nitride material would be separated from its original substrate and be of large surface area, free standing, and homogeneous in chemical composition. Variations of the percentages of major chemical elemental constituents in crystalline material should be less than around 5%, preferably less than around 1%, and most preferably less than around 0.1%.

The GaN crystalline material would then be cut into elongated strips that have a top and bottom elongated facet or plane whose crystallographic axis is generally along the direction of threading dislocations and other planar defects in the crystalline material. Current C-plane HVPE GaN substrates grown by methods know in the art; where growth generally occurs along the c-direction on C-plane sapphire substrates can be used. C-plan GaN wafers and boules are currently produced by Kyma Inc., Hitachi Chemical Corp., Sumitomo Chemical, and Mitsubishi Chemical Corporation.

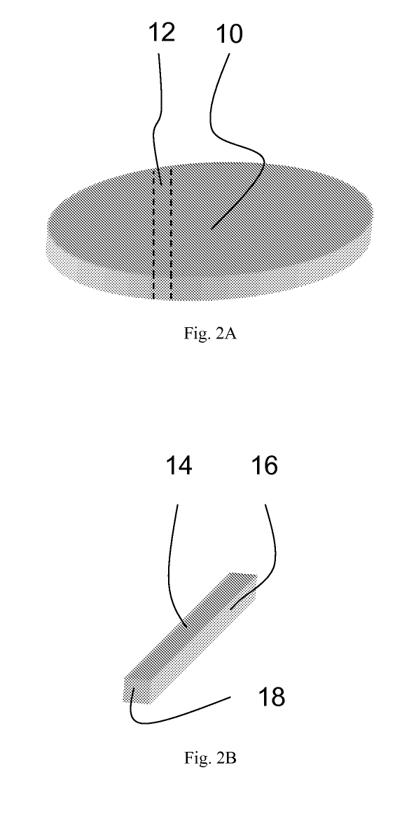

In one embodiment shown in FIG. 2A a portion 12 from a C-plane GaN wafer 2 can be removed to form a strip of GaN crystalline material FIG. 2B. The strip of FIG. 2B would be cut with two facets orientated or nearly oriented nearly to the two C-planes in which one is shown as 4, two elongated facets, perpendicular or nearly perpendicular to the C-plane, oriented or nearly oriented to the M-plane in which one is shown 6, and two facets, perpendicular or nearly perpendicular to the C-plane, of substantially shorter length oriented in the A-plane in which one is shown 8.

Other orientations can be used other than C-plane GaN crystalline material. GaN crystalline material originally grown in other crystallographic axis or directions such as A-pane GaN grown on R-plane sapphire can be also used as long as the majority of planer defects such as threading dislocations are substantially parallel to the subsequent lateral growth. For example one could use M-plane, A-plane, or semi-polar plane HVPE GaN by this technique to form low defect M-plane, A-plane, or semi-polar single crystal low-defect templates.

The strips may be of different lengths and cut from one or a plurality of GaN crystalline material. The lengths would be of the appropriate size so when subsequent lateral growth is performed, the low-defect single crystal material can be pieced together to form either partially faceted shapes such as squares and rectangles or fully faceted shapes such as the hexagonal shape templates whose largest surface area is oriented on the C-plane.

Lateral growth would now be performed on the strips by any of the growth techniques discussed above such as MOCVD and HVPE. The preferential growth techniques would be a solution base growth techniques such as ammonothermal or flux growth because of the ability to simultaneously grow on many strips at the same time and the uniform temperatures solution growth techniques can achieve.

Lateral growth in the range of 100 um-1 cm would be preferred to balance the number of low defect GaN pieces that would be needed from the lateral growth off the strips to produce a large surface area and the time that would be required to grow said pieces. For instance for a lateral growth rate of 100 μm/day for a particular growth technique like ammonothermal one could use this method herein to grow 5 mm wide pieces in 50 days. 10 quantity 5 mm wide pieces could then be pieced together to form a 50 mm wide square, rectangle, or hexagonal C-plane composite template.

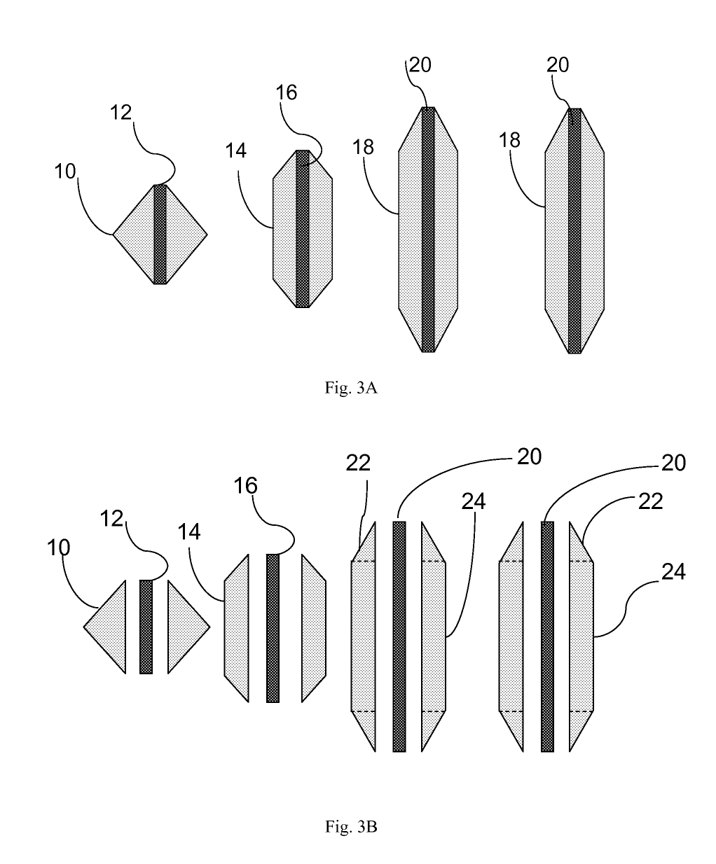

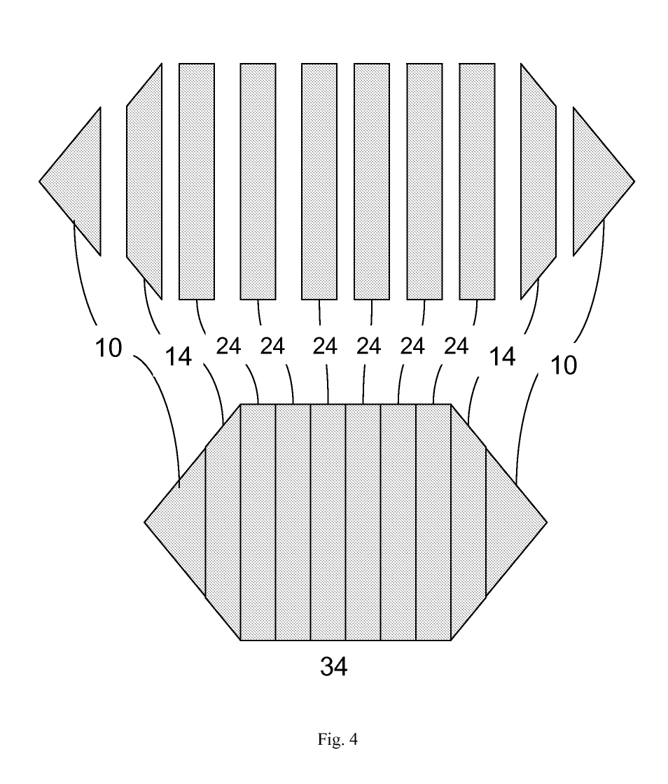

The growth on strips of various lengths in the a-axis are shown in FIG. 3A wherein the high defect material is shown cut or removed as seen in FIG. 3B. The lateral growth in FIG. 3A is in the a-axis of 12, 16, 20 in order to be able to form a hexagonal shaped template from the low defect single crystal pieces 10, 14, 22 in FIG. 3B. FIG. 4 shows the pieces in FIG. 3B processed into different geometric shaped sub-templates. The sub-templates in FIG. 4 comprising 2 strips of triangles 10, 2 strips of isosceles or near isosceles trapezoids 14, and six strips of rectangles 24 are pieced together to form a composite template that has a C-plane surface 34 forming a thin hexagonal prism.

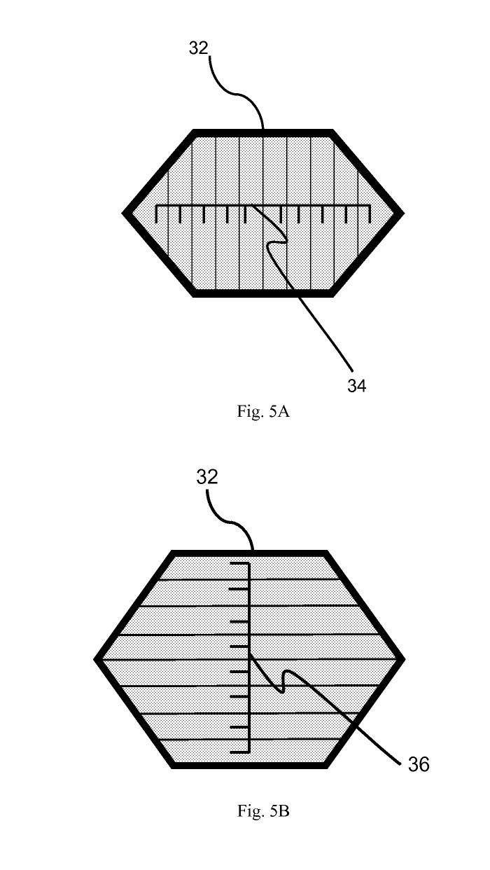

The composite template of FIG. 5A, 34 can be made one large contiguous volumetric crystalline material by a combination of wafer bonding, growth of an additional layer of the same material upon the individual pieces or sub-templates that make up the composite template, affixing a holder 32 with similar thermal expansion coefficient of the material, or by other methods know in the art of wafer bonding of crystalline materials. The pieces or sub-templates can be polished, annealed at high temperature and or pressure or other methods can be applied know in the art that will aid in forming a contiguous template with the smallest amount of defects being formed on the planes or in the vicinity of the planes where the individual sub-templates are physically connected. FIG. 5B also shows the c-plane surface of a thin composite template 36 in the geometric form of a hexagonal prism and surrounded by a holder 32. But the composite template in FIG. 5B is formed from low-defect sub-templates separated from m-plane lateral growth of a high-defect template. Lateral growth is preferred on the primary facets of the m-plane or a-plane to those skilled in the art due to the m-plane surface is step surface and the a-plane surface is a kink surface and thus the m-planes and a-planes will grow in more or less uniform growth rate which is conductive to low-defect growth and uniform impurity incorporation. This does not prohibit use of lateral growth techniques for defect reduction on non faceted and secondary faceted plane orientations because the growth conditions could be modified to those skilled in the art. Lateral growth on a particular growth facet could be optimize to produce uniform low-defect material at a high rate of growth by optimizing growth parameters such as solvents, mineralizers, dopants, surfactants, temperatures, and pressure.

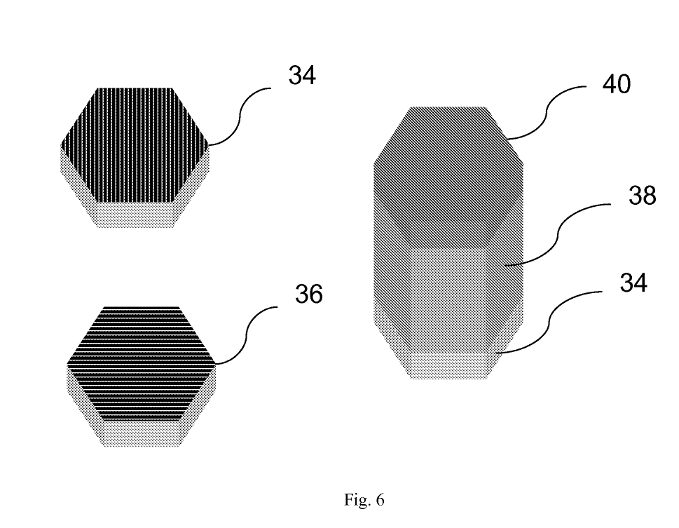

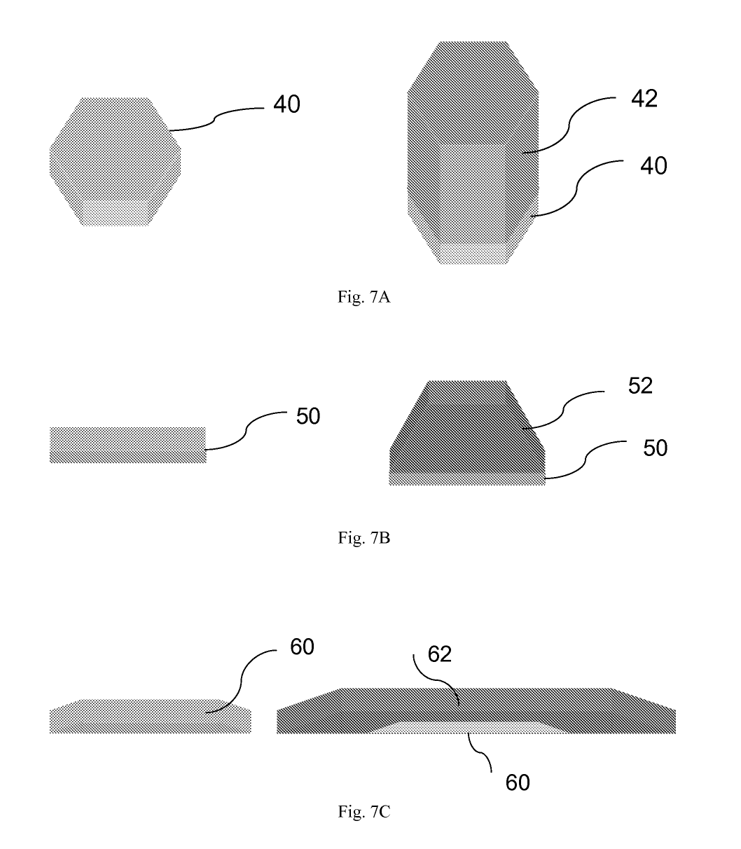

FIG. 6 shows a thin hexagonal prism composite template formed from laterally grown a-plane sub-templates 34 and another thin hexagonal prism composite template 36 formed from laterally grown m-plane sub-templates 36. Ether one of the composite templates 34 or 36 could be used to grow a thick GaN boule that has the geometrical form of a thick hexagonal prism as shown as two portions a thick lower layer 38 and a thin topmost layer 40. The topmost part of the hexagonal prism 40 could be removed from the boule and used as a template for successive GaN boule growth. The template 40 would a have a lower number of defects than the original composite template 34, because the majority of the defects in 34 are in the a-axis or are in directions on or near to planes that are perpendicular to the c-axis. The c-axis is the growth axis for boule 38, 40 in FIG. 6, thus the majority of the planar defects that occur during the binding of the individual sub-templates of the composite templates 34 and 36 will not propagate up into the boule. The topmost part of the boule 40 can then be processed into a very low-defect template to be used to grow an extremely thick low defect boule 42 as shown in FIG. 7A. Similar methods can be performed on directions other than the c-axis. For example thick HVPE a-plane GaN could on r-plane sapphire. The r-plane sapphire can be removed from the thick a-plane GaN. The a-plane GaN can be processed into long strips with the longest and widest facets along the c-plane. Lateral growth can now be done on the c-plane, the low-defect pieces removed and a composite a-plane template constructed. The a-plane composite template could be used to grow a thick GaN boule of the geometrical shape of a half or nearly half hexagonal prism. The topmost portion could be removed and processed into an a-plane low-defect GaN template as shown in FIG. 7B, 50. The a-plane template can now be used to grow a thick GaN boule in the shape or approximate shape of a half prism 52 as shown in FIG. 7B. Similar techniques can be used to produce a low-defect half hexagon boule 62 from a mostly m-plane template 60 as shown in FIG. 7C.

A low-defect nitride template or the pieces or sub-templates that make up a composite template using this method may have a concentration of dislocations and other line, plane, or volume defects of less than 10⁶ per centimeter square, preferably less than 10⁵ per centimeter square, and most preferably less than 10⁴ per centimeter square. A low-defect nitride template or the pieces or sub-templates that make up a composite template using this method should have variations of the percentages of major chemical elemental constituents of less than around 1%, preferably less than around 0.1%, and most preferably less than around 0.01%. Variation of unintentional impurities and native point defects and intentional dopants should be less than around 100%, preferably less than 10%, and most preferably less than 1%. The less variation of percentages of both the main constituents and impurities and dopants will correspond to a lower variation in lattice constants and thermal expansion coefficients each of the pieces and thus of the template and of the composite template as a whole.

Alternately the pieces or sub-templates above could be manufactured by other lateral growth techniques such as Dwinilski et al. that grow laterally on multiple edges or facets simultaneously or D'evelyn et al as described by PCT/US2007/023693 that grows laterally in cutouts in HVPE templates. These techniques are less preferable as said techniques are more complicated and costly than the inventive technique just described. But nonetheless could also be used as low-defect sub-templates if properly processed by employing techniques such as cutting, grinding, polishing, annealing to manufacture sub-templates of the proper orientation required to form a fully faceted composite template as discussed herein. Also the original high-defect GaN strip could be replace by an elongated plate by cutting plates that have a-plane, m-plane or other planes that are mostly perpendicular or even just offset from the C-plane of a thick high-defect HVPE boule. Current state of the art m-plane or a-plane non-polar HVPE plates have be manufacture with the existing knowledge with c-axis dimensions of around 5 mm. Therefore, low-defect material can be grown by the laterally growth techniques and methods discussed herein on non-polar plates. The low-defect lateral growth on large-area plates can be process into many more sub-templates than on thin strips with c-axis dimensions of less than 1 mm, thus decreasing the manufacturing time of the composite templates and thus lowering the cost of producing said templates.

Low-defect III-nitride single crystal grown by any technique that produces single crystal grains of sufficient size, low-defect density, uniform lattice constants, and uniform thermal expansion coefficients can be used as sub-templates. The lattice constants and thermal expansion coefficients should vary by less than 10⁻⁴, preferably less than 10⁻⁵, and most preferably less than 10⁻⁶. Such sub-templates can then be inventively formed into a composite template as described herein for use in the manufacture of low cost low-defect III-nitride boules using any current state of the art technique and future inventive method to grow said III-nitride boule upon said template or composite template by the inventive methods discussed herein.

The second sub-method described herein is to grow on a fully faceted template or fully faceted composite template that has the following properties:

1. Has less than 10⁵ dislocations, other line defects, planar defects, and volume defects over 95% of its area.
2. Has a lattice constant and thermal expansion coefficient less than 10⁻⁴ of the boule that will be grown upon said template.
3. Is chemically compatible with said boule.

Preferred faceting of said templates is that of or nearly of the major facets or lattice planes of the P6₃/mmc space group such as the (100) C-plane, (111) A-plane, and the (100) M-plane as shown in FIG. 7A 50, FIG. 7B 60, and FIG. 7C 70 respectively. C-plane composite templates as stated above are shown in FIG. 5.

Faceted or nearly faceted templates and composite templates can be obtained from method described herein or by any other method or process that produces templates with the stated requirements above. Current state of the art ammonothermal low-defect wafers as produced by the company Ammono Sp. and disclosed in Dwilinski et al, Bulk ammonothermal GaN, Journal of Crystal Growth, Volume 311, Issue 10, 1 May 2009, Pages 3015-3018 and R. Kucharski et al., Nonpolar GaN substrates grown by ammonothermal method, Appl. Phys. Lett. 95, 131119 (2009) would be suitable templates for subsequent bulk growth using the inventive methods described herein if said templates have fully faceted or nearly fully faceted hexagonal planes as shown in FIG. 7. Fully facet templates are important because in growth processes such as flux and ammonothermal which are near equilibrium processes, a non-faceted template with non-faceted edges or sides especially a circle which have all possible facets will cause defects and in many cases polycrystalline material to form. In non-equilibrium processes such as MOCVD and MBE it is important to get uniform gas distribution and a circular template is important. HVPE growth has equilibrium conditions in between solution growth and other vapor processes such as MBE and thus there are benefits and disadvantages of using circularly shaped templates or templates whose sides or edges are oriented on the major growth axes. Until HVPE growth reactors with greater control, uniformity of gas flows, and lower contaminant levels are invented, faceted templates would be preferred over circular templates. Another possible method of enablement would be to have the growth template or composite template in the form of a geometric surface comprising a single hexagon surrounded by six hexagons. Each of the six outer hexagons would have three outer facing m-plane surfaces that would form a larger geometric form with 18 m-plane outer edges or sides. These shapes made out of multiple hexagons might allow better overall optimization in which given a particular set of conditions surfaces comprised of multiple hexagonal geometric forms improve uniformity in gas flows over a single hexagon and achieve less defect formation on the edges or sides of the template than a circular template.

Inventive sub-method 1 and sub-method 2 discussed above will not produce thick large-area low-defect boules unless there is extremely small difference of lattice constants and small thermal expansion constants of the three separate growth processes employed as follows:
A. The process of forming high-defect free standing GaN
B. The process forming low-defect lateral growth on high defect GaN and forming a composite template or template
C. The process that grows large low-defect boules are grown on low-defect composite-templates or templates

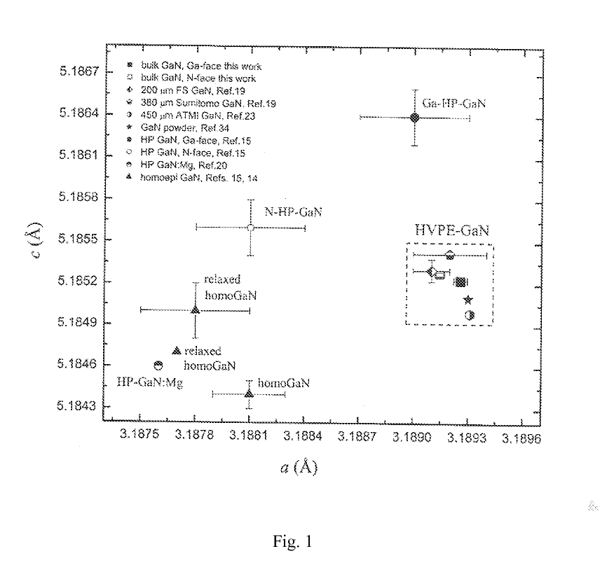

This is due to the fact of the CT, critical thickness, once surpassed a large number of dislocations will form as discussed in the background section and restated here Grzegory et. al claim that a lattice mismatch ˜1.6×10⁻⁴ of their HP GaN to HVPE material (see FIG. 1 in this application) was experimentally determined to correspond to a critical thickness of 30-50 μm. Thus a nominally standard HVPE growth technique know in the art was employed to grow greater than around 50 μm of standard HVPE GaN material on an HP GaN wafer where a large number of additional defects were generated due to growing past the CT, critical thickness, of the HP GaN substrate and the HVPE GaN material grown upon said HP substrate.

Thus using techniques know in the art; boules grown by the HVPE technique on low-defect templates manufactured by other growth techniques can only produce boules of thickness in the range of 1 mm or less without generating a large amount of additional defects in growing boule.

Thus there is a need of inventive art to allow for thick, greater than 1 mm, or preferably greater than 10 mm or most preferably greater than 100 mm, GaN and III-N boules on low-defect templates or composite templates.

The inventive art herein solves the problem lack of a method to grow thick, greater than 1 mm, boule growth on low-defect templates using HVPE growth techniques and other growth techniques by doping or alloying either the low-defect template or the subsequent boule growth or both to achieve almost exact lattice matching and thermal expansion coefficient matching of the GaN or III-N template or composite template and the thick GaN or III-N boule grown upon said template or composite template.

Determine of actual lattice parameters of current state of the art GaN and the group III-nitride thick films is complicated and hard to theoretically determine. Factors such as what type of dislocations are generated (line, screw, or mixed), the actual radius of dislocation core and actual burgers vector that corresponds to the type of misfit dislocation have to be taken into account. How point defects, both intrinsic and extrinsic, effect small changes to dislocation core and burgers vectors are also a factor. The growth rate, unintentional impurities (point defects) incorporated during growth process, Non-uniformities in gas flows and temperature gradients imposing small non-uniformities and thus a change in dopant profile could all change the boule lattice parameters and to a lesser degree the template or sub-template lattice parameters during growth. Also for high doping levels with electrical conducting dopants; lattice deformation can happen do to carrier thermodynamic effects on the lattice.

CT, critical thickness, is also a complicated process to determine theoretically. A rough estimate know in the art is CT in nanometers for thick GaN films ˜1/abs (f); f=lattice mismatch

Taken all this into account an estimate of Oxygen doped and Si doped GaN lattice mismatch and critical thickness for growth nominally undoped thick film and boule growth upon a doped low-defect template is shown in the tables below using the following reference for theoretical change of lattice with Si and Oxygen dopants, Chris G. Van de Walle, Effects of Impurities on the lattice parameters of GaN, Physical Review B 68, 165209 (2003) 1-5 and a compilation of many references to obtain a rough estimate of CT at the dopant levels listed with undoped GaN.

TABLE 1
Theoretical Lattice Mismatch and CT for given oxygen concentration
levels in Oxygen doped low-defect GaN Crystal vs. Undoped low-defect
GaN crystal

| Oxygen doping level | Lattice Mismatch | CT of | |
|---|---|---|---|
| of Doped GaN | to Undoped GaN | undoped GaN | |
| 10⁻²⁰ | ~+10⁻³ | ~2 | um |
| 10⁻¹⁹ | ~+10⁻⁴ | ~20 | um |
| 10⁻¹⁸ | ~+10⁻⁵ | ~200 | um |
| 10⁻¹⁷ | ~+10⁻⁶ | ~2 | mm |
| 10⁻¹⁶ | ~+10⁻⁷ | ~20 | mm |

TABLE 2
Theoretical Lattice Mismatch and CT for given silicon concentration
levels in silicon doped low-defect GaN Crystal vs. Undoped low-defect
GaN crystal

| Silicon doping level | Lattice Mismatch to | CT of | |
|---|---|---|---|
| of Doped GaN | Undoped GaN | undoped GaN | |
| 10⁻²⁰ | ~−10⁻⁴ | ~20 | um |
| 10⁻¹⁹ | ~−10⁻⁵ | ~200 | um |
| 10⁻¹⁸ | ~−10⁻⁶ | ~2 | mm |
| 10⁻¹⁷ | ~−10⁻⁷ | ~20 | mm |
| 10⁻¹⁶ | ~−10⁻⁸ | ~200 | mm |

If these rough estimates were correct or refined, the inventive art herein could be used to manufacture a low-defect template GaN or composite template in a hexagonal shape by one type of growth technique and either: 1) Dope, 2) Alloy, or 3) Dope and Alloy the boule growth that is deposited upon the template or composite template by another technique in such a way to get a lattice mismatch and thermal expansion mismatch that would correspond to a critical thickness, CT, that is less than and preferably substantially less than the thickness of the template or composite template at growth temperatures. Therefore, both the template and composite template would have an adequate lattice match and thermal expansion match during cool down to room temperature as to avoid significant defect generation during growth and/or cooling of said nitride boule upon said template or composite template.

One could also achieve low-defect boules by either doping, alloying, or doping and alloying said template to achieve an adequate lattice match or thermal expansion match to said boule to avoid CT of template during growth of nitride boule.

Finally one could dope, alloy, or dope and alloy: both the nitride template and said nitride boule to achieve an adequate lattice match and thermal expansion match to prevent a CT being reach.

Another innovative method is to combine doping and alloying to achieve close lattice and TEC matching of template or composite template with nitride boule; with thinning the low-defect template or composite template to the lowest practical thickness that is achievable with damaging or breaking said wafer or composite template.

The easiest way to comprehend this innovative idea is to think of the template as a thin film in comparison to the boule once the thickness of the boule surpasses that of the template. Upon initial growth on the template the boule is the thinner of the nitride material and the thinner material will form misfit dislocations and other defects before the thicker material once a CT is surpassed. If the thickness of boule surpasses that of the template without the CT being reach then the boule is the thicker of the two and since the template is thinner than the CT one can grow an unlimited thickness without misfit dislocations and other misfit defects forming. Thus the thinner the template or quasi template is; the smaller the lattice mismatch and TEC mismatch between the template and boule and if the CT is around 5× smaller than either the thickness of the template or composite template and the boule while it is growing upon the template or composite template; no misfit dislocations or defects will be generated.

Thus using Table 1 and Table 2 above as a theoretical construct, the inventive art herein can be used to grow a c-plane hexagonal shaped composite template with ˜1×10¹⁹ cm⁻³ oxygen and all other impurities were below detection limits one could achieve near lattice and TEC matching by growing a boule with another technique that was also doped with ˜1×10¹⁹ cm⁻³ oxygen. The same method could be done by just matching the dopants and impurities that have a concentration above 5×10¹⁷ cm⁻³ in both the template and the boule by using methods and techniques that are known in the art for doping bulk crystals by the various techniques such as ammonothermal, flux, vapor, and sublimation growth.

Alloying could also be used, so if one growth process used for template generation yielded 1×10¹⁹ cm⁻³ oxygen which makes the GaN lattice larger then one could alloy the boule with sufficient indium which also makes the lattice larger of the boule to achieve a large enough critical thickness to grown a thick slightly In alloyed GaN boule upon a oxygen doped GaN template or composite template.

This inventive method is needed because different growth techniques for GaN generate different impurity levels, due to the inherent nature and impurities generated by each technique that is directly related to each specific technique's processing equipment, temperatures, pressures, and chemical constituents.

Another example is if a low-defect GaN template or composite template can theoretically be thinned to ˜10 um then the template could have impurities in the range of around 1×10¹⁹ cm⁻³ and a low-defect essentially pure thick GaN boule may be grown without reaching the CT of the initially the boule during the beginning stages of growth and finally the template during the later stages of growth and no misfit defects will be generated during boule growth. Doping and Alloying and Thinning can be done at all levels of the boule development process to avoid the critical thickness of either the template or boule from being reached.

One mode of the many possible modes for enablement of forming a fully formed hexagonal prism with a thickness of greater than 5 cm and with six hexagonal side facets of about 10 mm long would be to serially perform steps A-F below.

A: Grow thick, greater than 5 mm, HVPE thick films on foreign substrates such as sapphire by currently know techniques by one skilled in the art in order to obtain around 2 mm×25 mm current state of the art HVPE m-plane templates

B: By doping and/or alloying of ammonothermal growth and thinning of m-plane GaN templates obtain low-defect lateral growth by an ammonothermal method on many m-plane GaN templates in which the lateral growth is low-defect because of near lattice and TEC matching of lateral growth with HVPE m-plane template in step A

C: Construct low-defect composite ammonothermal C-plane template hexagonal prism from processed low-defect ammonothermal lateral growth pieces from step B

D: By doping and/or alloying a HVPE growth technique know in the art grow 5 mm lattice matched and TEC matched HVPE GaN thick film on ammonothermal composite template in step C

E: Cut and process topmost portion HVPE hexagonal GaN thick film or boule in step D to obtain low-defect 100 um fully faceted HVPE template

F: By using same dopant, grow greater than 5 cm low defect HVPE hexagonal prism shape boule on low-defect doped alloyed HVPE template obtain in step E.

There are many modifications and additions to forming composite template so it will be contiguous and the pieces or strips making up the composite template will not separate. The strips may be bonded using high pressure annealing under high pressure nitrogen in a Hot Isostatic Press or any apparatus capable of achieving temperatures in any range of 1100-2500° C. and pressures of any range of 0-100K bar. Bonding under flowing nitrogen could also be used. Holders may be used to hold the pieces together making up the composite template.

Instead or in addition to bonding a thin layer of doped or alloyed near lattice match layer could be applied to one or both large area facets, or all exposed facets by any of nitride forming methods know in the art such as: Ammonothermal, MBE, MOCVD, or even HVPE before HVPE boule growth to aid in holding the composite template in place or to further enhance near exact lattice matching or for strain compensation. The inventive methods herein could be used for GaN, Group III-Nitrides, Any Nitride, or even any chemical element or compound that does not have a melting point at practical pressures or temperatures for industrial molten bulk crystal growth processes.

One possible procedure to get correct doping/alloy level to achieve lattice/thermal expansion match would be:
1) Measure template or composite template Rocking Curve and EPD
2) Grow ˜1 um of MBE, MOCVD, or HVPE GaN on Template or composite template with same impurity levels that will be incorporated during boule growth.
3) Measure lattice constant to see if material is strained
4) Repeat 1-3 with new template or composite template of same material and add enough dopant to minimize strain

5) When get correct dopant concentration use HVPE growth or other growth method know in the art to grow on template or composite template with proper dopant concentration as determined by step 4.

The final sub-method would be laser liftoff of lattice matched or nearly lattice matched templates or boules by alloying or doping either the template or boule in order to obtain an absorption profile on either the template or boule so a laser can be shown through the boule or template to decompose a thin layer at the interface of the template and boule and separate the boule from said template. The would be highly beneficial for a process like ammonothermal or HVPE where a film is grown to a thickness in the range of a μm or less to around a 100 μm on a large number of templates of one or more very large templates simultaneously. The expensive thick templates could be used over and over and a thin or thick film could be grown upon the templates to a thickness that allows some elastic deformation doing the laser lift off process. For example a GaN template can be used where a lattice matched AlInGaN template of 25 μm is grown on top of the template by a method know in the art. A laser can be used that is transparent to the AlInGaN template, but is absorbed into a few nanometers of the GaN template decomposing the GaN and separating the AlInGaN 25 μm film from the GaN template. A laser sheet may be used to lift the AlInGaN of one side and the laser could be scanned to the other side of the AlInGaN template. The 25 μm thickness of the AlInGaN thick film is thin enough to alloy for some elastic deformation a laser line can be used to scan across the GaN template which will separate the AlGaInN thick film without cracking or causing addition defects to the AlGaInN thick film or the GaN template. In this way large flexible low defect Nitride substrates could be formed. Using a method like ammonothermal many lattice matched films could be grown simultaneously and subsequently laser lift off to produce many low defect flexible substrates and the Nitride templates could be used multiple times. Many variations could be conceived for the innovative laser lift method discussed herein. Very large high-defect Nitride material could be grown on large sapphire wafers of greater than 4″, 8″, 12″ or more. The high defect material could be laser lift off by scanning a laser line or point laser across it and the film would be of such thickness to allow for elastic deformation so a portions of the nitride thin film could become separated from the sapphire wafer without forming additional dislocations or cracking. The high defect Nitride flexible sheet could now be used as described herein or other methods know in the art to make a low-defect template or composite template. A very large low-defect Nitride sheet could be obtained this way. A series of very large low-defect Nitride sheets can then be used to grow thick nitride boules or could be used to grow thinner Nitride films that will have elastic properties when laser lifted from the template they are grown on. If these substrates can be scaled to very large areas than a moving deposition method such as those used for thin film photovoltaic manufacturing methods know in the art can be used i.e. evaporation or other vapor transport methods of Al, Ga, In metals under flowing ammonia to form a Nitride layer on large templates that can be subsequently removed by laser lift off described herein and the substrates or templates reused many times to grow new Nitride layers or films with a low amount of defects. Thin layers less than 10 μm could be grown on a lattice matched Nitride template and an inexpensive metal, alloy, steel, or plastic could be deposited on top of the film. Using the laser lift techniques discussed herein the film and metal, ally, steel, or plastic could be separate from the Nitride template as a flexible substrate with a thin Nitride film on top. Other electromagnetic radiation may be used such as electron beams, directed light from a arc-lamp or one or more LEDs, or any method that can heat a thin layer between a Nitride template and a Nitride thin film where the thin film is thin enough to have elastic properties so that a portion can be removed at a time scanning electromagnetic radiation with sufficient properties to remove the Nitride template from the Nitride thin film without adding substantial defects or cracking either the film or the template. The laser liftoff could also be used to grow a thick boule on a thin template which will have elastic properties when removed and then lift off the template so the thin template can be reused to grow another boule.

The methods herein could be successively used multiple times to achieve desired lattice constants, defect levels, conductivity, III-N composition, transparency, and other properties by using different concentrations and combinations of incorporating dopants and alloys in both template and boule during growth and post processing techniques such as annealing at high temperature in a high partial pressure of nitrogen. These methods above can be applied multiple times with slight modifications of one or more aspects of the methods to achieve desirable qualities of said nitride substrates such as low defect levels, large surface areas, thick boule production, high or low conductivity, etc.

Many slight variations and modifications could be applied to the inventive methods described herein and in no way should these slight modifications or modifications be interpreted as separate inventive art disjoined for what is described herein.

### EXAMPLES

The following examples serve to illustrate the features and aspects offered by embodiments of the invention, and do not limit the invention thereto.

### Example 1

HVPE strips were used to grow laterally m-plane acidic ammonothermal low defect GaN material using methods similar to D'evelyn et al. in international patent application PCT/US2007/023693 with around the impurity concentrations of that which is claimed by D'evelyn et al. as shown in table below. A c-plane GaN composite wafer in the shape of a thin hexagonal prism is constructed by joining the low-defect m-plane pieces which have previously been laser cut, polished, and bonded at high nitrogen pressure of around 10K bars and at a temperature of around 1700° C. 2 um thick MOCVD layers are grown on both the gallium face (C+facet) and nitrogen face (C-facet) that have impurity concentrations nearly equivalent in the table below.

SIMS measurement of Concentration on Atoms/CC

| Face | Oxygen | Hydrogen | Carbon | Silicon |
|---|---|---|---|---|
| Ga | 5 × 10¹⁷ | 3 × 10¹⁸ | 4 × 10¹⁶ | 6 × 10¹⁶ |
| N | 4 × 10¹⁷ | 2 × 10¹⁸ | 5 × 10¹⁶ | 2 × 10¹⁶ |

Concentration Data of Ga face and Nitrogen Face of high pressure acidic ammonothermal lateral growth as shown by D'evelyn et al. in international patent application PCT/US2007/023693 paragraph 138.

A wafer bowing measurement device is used during growth to insure low bowing which corresponds to a low lattice mismatch. X-ray rocking curves, transmission imagery, and reflection imagery from a synchrotron x-ray white beamline is used on the composite template to confirm dislocation density of less than 10³ dislocations per cm² and no visible plane or volume defects. The composite GaN template is placed in a HVPE reactor known in the art. A small flow of water vapor is added to a standard HVPE growth run known in the art to allow for a small lattice mismatch of less than 10⁻⁶ of the HVPE GaN growth on the GaN composite template which corresponds to a CT of greater than 2 mm. The composite C-plane Ammono/MOCVD template is 200 um thick. 100 mm of low defect GaN growth is grown on the composite template using the HVPE technique. A wafer bowing measurement device is used and no measurable bow is determined during growth. The 100 mm thick boule is in the shape of a hexagonal prism. 200 quantity 200 um thick low-defect GaN wafers are processed from said boule that have a circular shape and have less than 10⁴ dislocations per cm².

### Example 2

Example 1 is modified by using low defect sections of low-defect GaN manufactured by the Sumitomo “A-Deep” technique with impurity levels near those described in example 1 as the pieces of the composite template used for HVPE boule growth.

### Example 3

A high purity ammonothermal forward grade soluble solution is used to grow low defect lateral a-plane growth from multiple C-plane flux grown strips produced by a sodium flux method know in the art to grow GaN. The low-defect strips are placed together in a composite template in the shape of a thin hexagonal prism. X-ray rocking curve measurements on each strip confirm lattice parameter measurements that are within 10⁻⁷ of the flux grown strips. The same flux method know in the art is used to grow a 5 cm thick low-defect GaN boule on the composite template.

### Example 4

A series of 2″ C-plane Ammonothermal Alkaline 200 μm thick wafers shape in the thin cylinder grown and processed by methods know in the art are measured by x-ray rocking curve data to obtain lattice parameters. All the lattice constants of the Ammonothermal GaN wafers are within 10⁻⁶ of each other. Through experimentation on several wafers the proper process parameters and Al and In compositions is determined to obtain lattice matched AlInGaN wafers with 25% atomic composition gallium and 25% atomic composition of Al and In and 50% composition of nitrogen when grown by a HVPE method know in the art. The remaining GaN wafers are used in a HVPE reactor to grow a 50 μm lattice matched AlInGaN layers on the GaN wafers. A laser is used to scan across each of the AlInGaN layers. During laser scanning the laser is transparent to the AlInGaN layers and is transmitted through the AlInGaN layers to where it is absorbed on the surface of the GaN wafers. The laser is started at one edge where the nitrogen can escape during the decomposition of a thin layer of GaN. As the laser scans across each wafer, a mechanism pulls up on the previously scanned layers detaching a portion of the AlInGaN layer from the GaN wafer. As the laser is scanned the AlInGaN is in effect peeled off the GaN wafer. Few or no additional defects are generated from the scanning as the AlInGaN layer has elastic properties and undergoes predominately elastic stress during peeling at the decomposition interface caused by laser irradiation. The process is repeated multiple times producing several hundred flexible low-defect AlInGaN substrates with less than 10⁻⁵ dislocations from only 10 GaN substrates.

### Example 5

An ammonothermal low-defect wafer knows in the art in the shape of a 50 μm thick hexagonal trapezoid is used as a template to grow a lattice matched HVPE boule. The HVPE growth has a slight lattice variation that has a critical thickness of 100 μm. After 75 μm of growth both the HVPE and ammonothermal template have some elastic strain but no additional defects are generated. As the boule proceeds to grow most of the strained is transferred to the ammonothermal template. After growth the boule is separated from the template and the strain is released from both the template and boule.

### INCORPORATED HEREIN AS REFERENCES

Kensaku Motokia, Takuji Okahisaa, Ryu Hirotaa, Seiji Nakahatab, Koji Uematsua, Naoki Matsumotob, Dislocation reduction in GaN crystal by advanced-DEEP, Journal of Crystal Growth 305 (2007) 377-383
Chris G. Van de Walle, Effects of Impurities on the lattice parameters of GaN, Physical Review B 68, 165209 (2003) 1-5
J. Smalc-Koziorowska, G. Kamler, B. Lucznik and I. Grzegory, Structural defects in GaN crystals grown by HVPE on needle-shaped GaN seeds obtained under high N2 pressure, Journal of Crystal Growth, Volume 311, Issue 5, 15 Feb. 2009, Pages 1407-1410
M. K. Kelly, O. Ambacher, R. Dimitrov, R. Handschuh, M. Stutzmann, Optical Process for Liftoff of Group III-Nitride Films, Phys. Stat. Sol. Volume 159, R3, 1997
Robert Kucharski, Marcin Zajac, Roman Doradzinski, Jerzy Garczynski, Leszek Sierzputowski, Robert Kudrawiec, Jaroslaw Serafinczuk, Jan Misiewicz, and Robert Dwilinski, Structure and Optical Properties of Semipolar GaN Substrates Obtained by Ammonothermal Method, Applied Physics Express 3 (2010) 101001.

I claim:

1. Metal nitride single crystal boule grown by HVPE techniques of the geometrical form of a cylinder, a hexagonal prism, or partial hexagonal prism wherein:
a. the thickness of the boule is greater than 1 cm in length
b. the surface area of the largest plane of the boule is greater than 20 cm²
c. the dislocation density of the boule is less than 10⁸ per cm³
d. the boule is substantially free of grain boundaries and other planar defects

2. The metal nitride boule of claim 1 where said metal nitride is a material substantially composed of the chemical element nitrogen and any element or elements in Group III of the periodic table using the American CAS numbering system, including group IIIA (equivalent to group 3 in the new IUPAC numbering system) which include the elements of scandium (Sc) and yttrium (Y), and group IIIB (which is equivalent to group 13 in the new numbering IUPAC system) which include the elements of boron (B) gallium (Ga), aluminum (Al), indium (In), and thallium (Tl) and all corresponding alloys of group III nitrides such as: InGaN, InAlN, AlGaN, AlBN, ScGaN, AlGaInN, etc.

3. The metal nitride boule of claim 1 may contain one or more elements of the periodic table such as Si, O, Zn, Mg, Be, Eu, Tb, Ho, Er, Cr, Mn, Fe, Ni, Co and others at levels to achieve desired electrical conductivity, optical, or magnetic properties of said MN boule.

4. The metal nitride boule of claim 1 which contains elements of the periodic table such as Si, O, Cl and other elements that originate from a hydride vapor phase epitaxial (HVPE) technique.

5. The metal nitride boule of claim 1 annealed at high temperature and high nitrogen pressure or high nitrogen flow to relieve elastic strain and allow uniformity of point defects in said nitride boule.

6. Metal nitride large-area low-defect semiconductor wafers processed from said nitride boule of claim 1

7. A method for making thick low-defect large-surface-area metal nitride boules which comprises the following steps of:
a. Providing a low-defect metal nitride template
b. Using a vapor phase growth or solution phase growth method to grow a thick low-defect metal nitride boule on said metal nitride template wherein at least one of the metal nitride template or the metal nitride boule is doped or alloyed to obtain nearly exact lattice matching and thermal expansion matching of the metal nitride template with the metal nitride boule during growth of the metal nitride boule

8. The metal nitride boule and metal nitride template of claim 7 where said metal nitride is a material substantially composed of the chemical element nitrogen and any element or elements in Group III of the periodic table using the American CAS numbering system, including group IIIA (equivalent to group 3 in the new IUPAC numbering system) which include the elements of scandium (Sc) and yttrium (Y), and group IIIB (which is equivalent to group 13 in the new numbering IUPAC system) which include the elements of boron (B) gallium (Ga), aluminum (Al), indium (In), and thallium (Tl) and all corresponding alloys of group III nitrides such as: InGaN, InAlN, AlGaN, AlBN, ScGaN, AlGaInN, etc.

9. The method of claim 7 wherein the low-defect metal nitride is replace by a low-defect metal nitride composite template that is formed by a plurality of low-defect sub-templates that are place together and processed so a to from a contiguous geometric shape.

10. The method of claim 7 wherein the metal nitride template is in the geometrical form of a cylinder, hexagonal prism, or partial hexagonal prism.

11. The method of claim 9 wherein the metal nitride composite template is in the geometrical form of a cylinder, hexagonal prism, or partial hexagonal prism.

12. The method of claim 9 where the sub-templates are formed by lateral growth on a metal nitride strip in which the majority of threading or misfit dislocations are generally perpendicular to the lateral growth and the high defect metal nitride strip is removed from the lower defect lateral growth

13. A method to remove a low defect metal nitride film from a template wherein:
a. A form of electromagnetic radiation is mostly transparent to one of the film or template and is absorbed to the other.
b. The electromagnetic radiation is passed through whichever the film or template it is transparent to
c. The electromagnetic radiation is absorbed in whichever the film or template it is not transparent to
d. The absorption of the electromagnetic radiation causes a portion of the film and template to separate
e. The film is thin enough to have the partial separation cause mostly elastic deformation until full separation is completed

14. The method of claim 13 wherein a laser is the source of electromagnetic radiation

15. The method of claim 13 wherein multiple thin films can be grown on the same template and removed

16. The method of claim 13 wherein the thin and template are nearly lattice matched

17. The method of claim 13 wherein doping at least one of the thin film or layer changes the electromagnetic absorption properties of at least one of the thin film or layer

18. The method of claim 13 wherein alloying at least one of the thin film or layer changes the electromagnetic absorption properties of at least one of the thin film or layer

19. The method of claim 13 wherein alloying or doping at least one of the thin film or layer changes the electromagnetic absorption properties of at least one of the thin film or layer while having the film and the layer nearly lattice matched

20. The method of claim 13 wherein a low-defect flexible metal nitride film with less than 10⁶ per cm² dislocations is separated from said template
